(19) United States
(12) Patent Application Publication
(10) Pub. No.: US 2006/0288569 A1
(43) Pub. Date: Dec. 28, 2006

(54) Electronic circuit board assembly fixturing device and method of making electronic circuit board assemblies

(76) Inventors: J. David Carlson, Cary, NC (US); Richard Wilder, Monacure, NC (US)

Correspondence Address: LORD CORPORATION;PATENT & LEGAL SERVICES, 111 LORD DRIVE, CARY, NC, 27512, US

(21) Appl. No.: 11/473,553

(22) Filed: Jun. 23, 2006

Related U.S. Application Data
(60) Provisional application No. 60/693,292, filed on Jun. 23, 2005.

(51) Int. Cl. H05K 3/36; B23P 19/00

(52) U.S. Cl. 29/830; 29/423; 29/760; 29/799; 235/449

(57) ABSTRACT

The invention includes an electronic circuit board assembly fixturing support device for supporting an electronic circuit board during an assembly process and a method of making an electronic circuit board assembly with the electronic circuit board assembly fixturing support device. The electronic circuit board support device includes a plurality of extendable support legs which have distal ends for engaging and supporting the electronic circuit board when extended to supporting leg extended lengths, with the device including a magnetic field generator for generating a magnetic field wherein the magnetic field generator magnetic field magnetically locks the supporting legs extended lengths in order to maintain the engagement and support of the electronic circuit bard during an electronic circuit bard assembly process to make electronic circuit bard assembly.

### CROSS REFERENCE

This application claims the benefit of, and incorporates by reference, U.S. Provisional Patent Application No. 60/693,292 filed on Jun. 23, 2005.

### FIELD OF THE INVENTION

The present invention relates to electronic circuit board assembly devices and methods of making electronic circuit board assemblies. More particularly the invention relates to a method of supporting and fixturing an electronic circuit board during an assembly process of making the electronic circuit board assembly.

### BACKGROUND OF THE INVENTION

There is a need for electronic circuit board assembly devices for supporting electronic circuit boards during an assembly process of making the electronic circuit board assembly, such as when the circuit board is being populated with components, such as during the mounting of components to the circuit board upper surface. There is a need for an economically feasible method of making electronic circuit board assemblies. There is a need for a robust fixturing device and method of making circuit board assemblies that provides beneficial efficiencies. There is a need for an economically feasible method of making electronic circuit board assembly fixturing support devices.

### SUMMARY OF THE INVENTION

The invention includes an electronic circuit board assembly fixturing support device for supporting an electronic circuit board during an assembly process and a method of making an electronic circuit board assembly with the electronic circuit board assembly fixturing support device. The electronic circuit board support device includes a plurality of extendable support legs which have distal ends for engaging and supporting the electronic circuit board when extended to supporting leg extended lengths, with the device including a magnetic field generator for generating a magnetic field wherein the magnetic field generator magnetic field magnetically locks the supporting legs extended lengths in order to maintain the engagement and support of the electronic circuit board during an electronic circuit board assembly process to make electronic circuit board assembly.

The invention includes a method of supporting an electronic circuit board during an electronic circuit board assembly process to make electronic circuit board assembly. The method includes providing an electronic circuit board, providing and electronic circuit board support device including a magnetic field generator for generating a magnetic field with the electronic circuit board support device including a plurality of extendable support legs. The method includes extending the extendable support legs into contact with the electronic circuit board and generating a magnetic field with the magnetic field generator to lock the extended support legs in contact with the electronic circuit board wherein the extended support legs support the electronic circuit board during the electronic circuit board assembly process to provide a supported electronic circuit board to make the electronic circuit board assembly.

The invention includes a method of making an electronic circuit board fixturing support device for supporting an electronic circuit board. The method includes providing a magnetic field generator for generating a magnetic field, providing a plurality of extendable support legs with the support legs extendable for contact with an electronic circuit board, and disposing the extendable support legs proximate the magnetic field generator wherein the magnetic field magnetically locks a plurality of extended support positions of the extendable support legs.

The invention includes a method of supporting a rigid electronic circuit board member to make an electronic circuit board assembly, with the method including providing a rigid member to be supported, providing a rigid member support device including a magnetic field generator for generating a magnetic field with the rigid member support device including a plurality of extendable support pin legs. The method includes extending the extendable support pin legs into contact with the rigid member, generating a magnetic field with the magnetic field generator to lock the extended support legs in contact with the rigid member wherein the extended support legs temporarily support the rigid member during an assembly process.

The invention includes a rigid electronic circuit board member assembly fixturing support device for supporting a rigid electronic circuit board member during an assembly process. The rigid electronic circuit board member support device includes a support base and a plurality of pneumatically extendable support pin legs pneumatically extendable away and upward for the support base with the plurality of support legs having a plurality of extended position supporting leg extended lengths. The support legs have a distal end for engaging and supporting the rigid board member when extended to the supporting leg extended lengths. The rigid board member assembly fixturing support device includes an electromagnetic coil for generating a magnetic field wherein the electromagnetic coil magnetic field magnetically locks the supporting legs extended lengths in order to maintain the engagement and support of the electronic circuit board rigid member.

The invention includes a method of magnetically locking a position of a movable support member. The method includes providing a magnetic position lock including an electromagnetic coil magnetic field generator with a first pole member and a second pole member. The magnetic position lock includes a magnetic position lock target, with the magnetic position lock target proximate the electromagnetic coil magnetic field generator, with the magnetic position lock target movable relative to the electromagnetic coil magnetic field generator. The method includes supplying a locking direct current to the electromagnetic coil magnetic field generator to lock a movable position of the magnetic position lock target into a magnetically locked support position, and supplying an unlocking reverse direction direct current to the electromagnetic coil magnetic field generator to unlock the magnetic position lock target from the magnetically locked position.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description are exemplary of the invention, and are intended to provide an overview or framework for understanding the nature and character of the invention as it is claimed. The accompanying drawings are included to provide a further understanding of the invention, and are incorporated in and constitute a part of this specification. The drawings illustrate various embodiments of the invention, and together with the description serve to explain the principals and operation of the invention.

### BRIEF DESCRIPTION OF THE DRAWINGS

FIG. 1 shows an electronic circuit board assembly fixturing support device and method of supporting an electronic circuit board.

FIG. 2 shows an electronic circuit board assembly fixturing support device.

FIG. 3A-B show components of an electronic circuit board assembly fixturing support device.

FIG. 4 shows an electronic circuit board assembly fixturing support device and method of supporting an electronic circuit board in the making of an electronic circuit board assembly.

FIG. 5 shows an electronic circuit board assembly fixturing support device and method of supporting an electronic circuit board.

FIG. 6 shows an electronic circuit board assembly fixturing support device and method of supporting an electronic circuit board.

FIG. 7 shows an electronic circuit board assembly fixturing support device and method of supporting an electronic circuit board.

FIG. 8A-B show a prior art method as compared with FIG 8C-D showing an electronic circuit board assembly fixturing support device and method of supporting an electronic circuit board in the making of an electronic circuit board assembly.

FIG. 9A-B shows an electronic circuit board assembly fixturing support device and method of supporting an electronic circuit board.

FIG 10A-C shows an electronic circuit board assembly fixturing support device and method of supporting an electronic circuit board.

FIG 11A-D shows an electronic circuit board assembly fixturing support device and method of supporting an electronic circuit board.

FIG 12 shows a control system and method of controlling an electronic circuit board assembly fixturing support device.

FIG. 13 shows a control logic system and method of controlling an electronic circuit board assembly fixturing support device.

### DETAILED DESCRIPTION

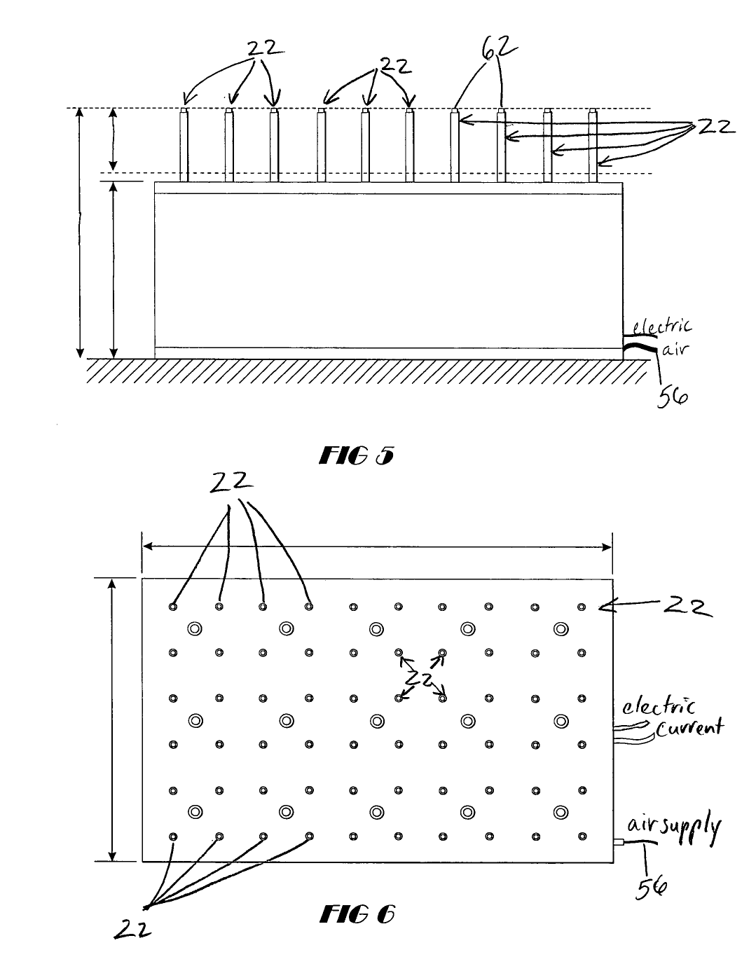

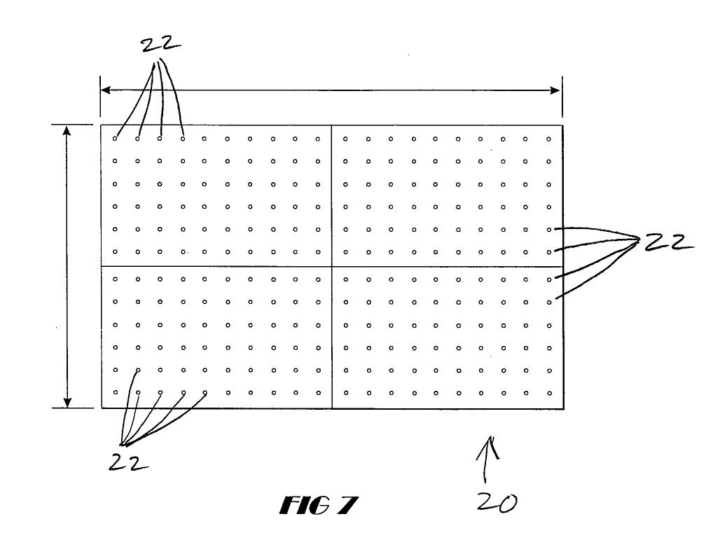

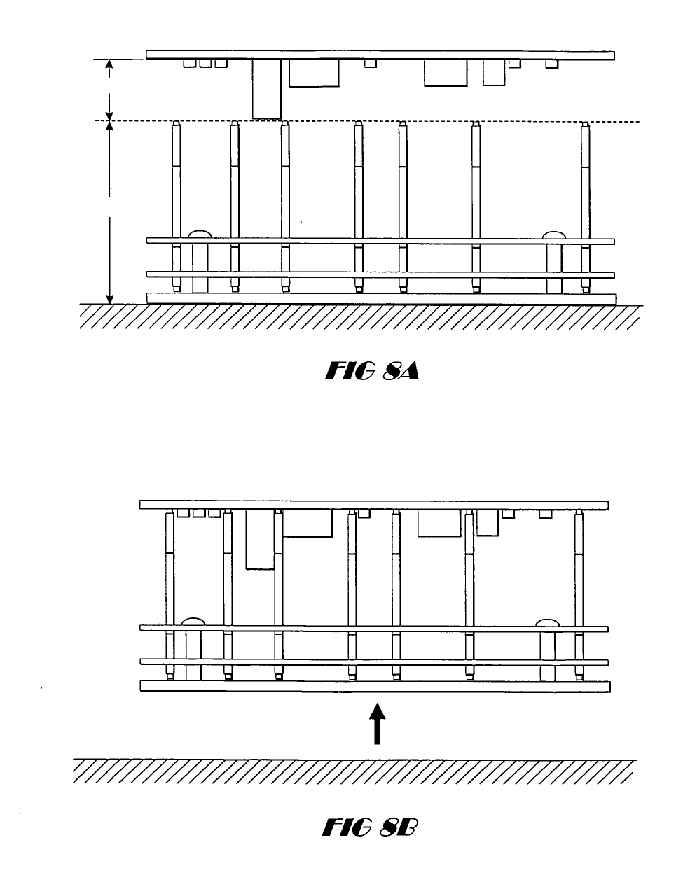

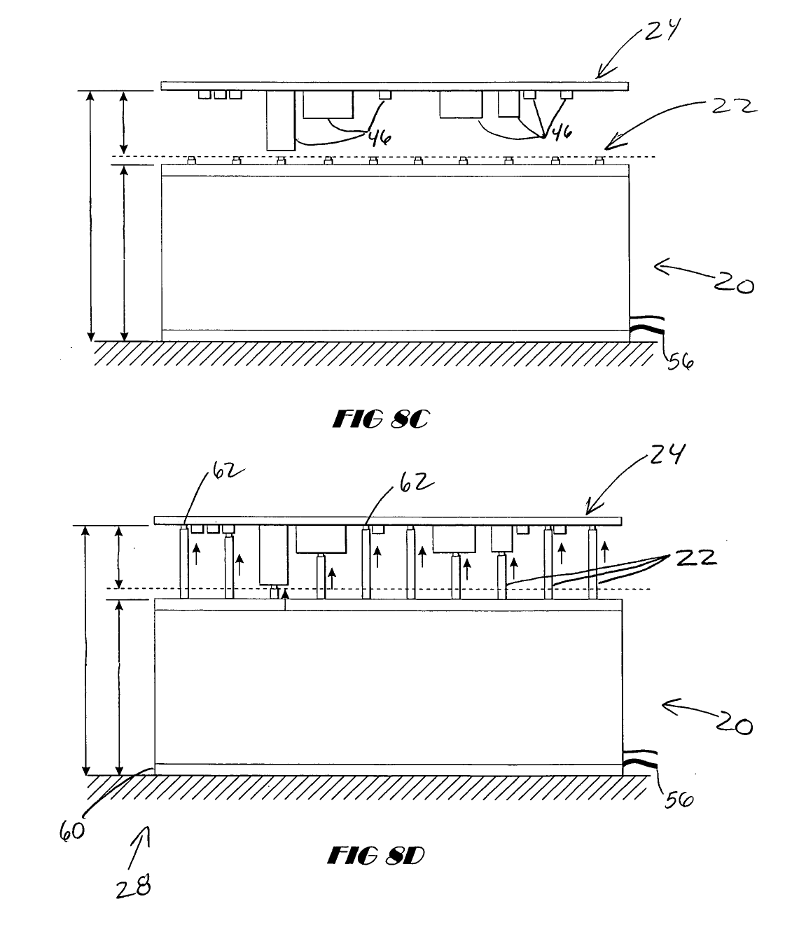

Reference will now be made in detail to the present preferred embodiments of the invention, examples of which are illustrated in the accompanying drawings. The invention includes an electronic circuit board assembly fixturing support device for supporting an electronic circuit board during an assembly process and a method of making an electronic circuit board assembly with the electronic circuit board assembly fixturing support device, preferable such as shown in FIG. 1-13.

The electronic circuit board support device includes a plurality of extendable support legs which have distal ends for engaging and supporting the electronic circuit board when extended to supporting leg extended lengths, with the device including a magnetic field generator for generating a magnetic field wherein the magnetic field generator magnetic field magnetically locks the supporting legs extended lengths inoder to maintain the engagement and support of the electronic circuit bard during an electronic circuit board assembly process to make electronic circuit bard assembly. The invention includes a method of supporting an electronic circuit board during an electronic circuit board assembly process to make electronic circuit bard assembly. The method includes providing an electronic circuit board, providing an electronic circuit board support device including a magnetic field generator for generating a magnetic field with the electronic circuit board support device including a plurality of extendable support legs. The method includes extending the extendable support legs into contact with the electronic circuit board and generating a magnetic field with the magnetic field generator to lock the extended support legs in contact with the electronic circuit board wherein the extended support legs support the electronic circuit board during the electronic circuit board assembly process to provide a supported electronic circuit board to make the electronic circuit board assembly. The invention includes a method of making an electronic circuit board fixturing support device for supporting an electronic circuit board. The method includes providing a magnetic field generator for generating a magnetic field, providing a plurality of extendable support legs with the support legs extendable for contact with an electronic circuit board, and disposing the extendable support legs proximate the magnetic field generator wherein the magnetic field magnetically locks a plurality of extended support positions of the extendable support legs. The invention includes a method of supporting a rigid electronic circuit board member to make an electronic circuit board assembly, with the method including providing a rigid member to be supported, providing a rigid member support device including a magnetic field generator for generating a magnetic field with the rigid member support device including a plurality of extendable support pin legs. The method includes extending the extendable support pin legs into contact with the rigid member, generating a magnetic field with the magnetic field generator to lock the extended support legs in contact with the rigid member wherein the extended support legs temporarily support the rigid member during an assembly process. The invention includes a rigid electronic circuit board member assembly fixturing support device for supporting a rigid electronic circuit board member during an assembly process. The rigid electronic circuit board member support device includes a support base and a plurality of pneumatically extendable support pin legs pneumatically extendable away and upward from the support base with the plurality of support legs having a plurality of extended position supporting leg extended lengths. The support legs have a distal end for engaging and supporting the rigid board member when extended to the supporting leg extended lengths. The rigid board member assembly fixturing support device includes an electromagnetic coil for generating a magnetic field wherein the electromagnetic coil magnetic field magnetically locks the supporting legs extended lengths in order to maintain the engagement and support of the electronic circuit board rigid member. The invention includes a method of magnetically locking a position of a movable support member. The method includes providing a magnetic position lock including an electromagnetic coil magnetic field generator with a first pole member and a second pole member. The magnetic position lock includes a magnetic position lock target, with the magnetic position lock target proximate the electromagnetic coil magnetic field generator, with the magnetic position lock target movable relative to the electromagnetic coil magnetic field generator. The method includes supplying a locking direct current to the electromagnetic coil magnetic field generator to lock a movable position of the magnetic position lock target into a magnetically locked support position, and supplying an unlocking reverse direction direct current to the electromagnetic coil magnetic field generator to unlock the magnetic position lock target from the magnetically locked position.

The invention includes an electronic circuit board assembly fixturing support device 20 for supporting an electronic circuit board during an assembly process. The electronic circuit board support device includes a support base and a plurality of extendable support pin legs. The support legs are extendable outward and away from the support base with a supporting leg extended length. The support legs are independently extendable outward from the support base with each supporting leg preferably having an independent height extended length position. Preferably adjacent legs are extended to different support height positions with the height of each extended support leg not dependent on the height of its neighboring support legs, with one leg having a relatively short extended length and another leg having a relatively long extended length. The support legs have a distal end for engaging and supporting the electronic circuit board when extended to the supporting leg extended lengths. The electronic circuit board assembly fixturing support device includes a magnetic field generator for generating a magnetic field wherein the magnetic field generator magnetic field magnetically locks the supporting legs extended lengths inorder to maintain the engagement and support of the electronic circuit board during an electronic circuit board assembly process. Preferably the device includes a compressed gas source for extending the support legs to the supporting leg extended lengths, preferably a compressed air conduit for supplying compressed air for extending the support legs to the supporting leg extended lengths. Preferably the device includes a first magnetic pole piece, a second magnetic pole piece, and an electromagnetic coil wherein a current supplied to the coil magnetically locks a plurality of the supporting legs with the supporting legs extended lengths. Preferably the device support base is comprised of a housing, with the housing pneumatically sealed to control an escaping compressed gas. Preferably the support base housing includes housing pieces and components which are sealed, such as with gasket sealant 54, wherein compressed air is channeled and controlled to exit the housing proximate the extendable support legs so the supplied compressed gas extends the legs. Preferably the legs extend out from the support base housing through housing leg bearings, preferably cylindrical plastic tubular conduit bearings, with the air exiting the housing between the housing leg bearings and the legs. Preferably the method of making electronic circuit board assemblies includes supporting the circuit board with the extended legs during an assembly process, preferably supporting the circuit board from the bottom underside while components and/or connections are completed on the upper topside, such as by soldering. Preferably the method of making an electronic circuit board assembly includes supporting the circuit board lower surface with the extended legs during a high speed component placement mounting assembly process in a circuit board high speed placement machine, preferably in a surface mount component placement machine, with the legs supporting the circuit board during the placement of surface mount device components onto the circuit board to make the support circuit board assembly with the mounted components.

The invention includes a method of supporting an electronic circuit board during an electronic circuit board 24 assembly process 28. The method includes the steps of providing an electronic circuit board 24 and providing an electronic circuit board support device 20 including a magnetic field generator 26 for generating a magnetic field. The provided electronic circuit board support device 20 includes a plurality of extendable support pin legs 22. The method includes extending the extendable support pin legs 22 into contact with the electronic circuit board 24 and generating a magnetic field with the magnetic field generator 26 to lock the extended support legs 22 in contact with the electronic circuit board 24 wherein the extended support legs 22 support the electronic circuit board 24 during an electronic circuit board assembly process 28. Extending the extendable support pin legs 22 into contact with the electronic circuit board 24 preferably includes pneumatically extending the support legs 22 into contact with the electronic circuit board 24. Preferably the magnetic field generator 26 includes an electromagnetic coil 30 and generating the locking magnetic field preferably includes supplying a locking electrical current to the coil to generate the magnetic field to lock the extended support positions of the support legs 22. Preferably the magnetic field generator 26 includes a first and second pole (N and S magnetic poles 32), with the magnetic poles 32 magnetically frictionally engaging the support legs 22. Preferably the locking electrical current is supplied to the electromagnetic coil 30 with the magnetic poles 32 magnetically frictionally locking the position of the extended support legs 22. Preferably the method includes reversing the electrical current supplied to the electromagnetic coil 30 to provide a demagnetizing field within the extended support positions of the support legs 22 are unlocked. Preferably the plurality of extendable support pin legs 22 includes a first leg 34, a second leg 36, and a third leg 38 and the first leg 34 is raised to a first length supporting position 40, the second leg 36 is raised to a second length supporting position 42, and the third leg 38 is raised to a third length supporting position 44, preferably with the lengths non-equal, with the extended leg heights independent of each other, preferably with the legs 22 extended until they come into support contact with the rigid circuit board and its underside rigid components 46. Providing the electronic circuit board 24 support device 20 including a magnetic field generator 26 for generating a magnetic field and a plurality of extendable support pin legs 22, preferably includes providing the electronic circuit board 24 support device 20 with a first magnetic field generator 26 electromagnetic coil 30 and the first set of extendable support pin legs 22, and a second magnetic field generator 26 electromagnetic coil 30 and a second set of extendable support pin legs 22 wherein the first electromagnetic coil 30 is energized to magnetically lock the extended support positions of the first set of extendable support pin legs 22, and the second electromagnetic coil 30 is energized to magnetically lock the extended support positions of the second set of extendable support pin legs 22. Preferably multiple adjacent rows of support legs 22 are locked by corresponding multiple longitudinally extending electromagnetic coil 30s to support the electronic circuit board 24 during the electronic circuit board 24 assembly process 28. Preferably the electronic circuit board 24 support device 20 is comprised of a housing 48, preferably with the housing 48 pneumatically sealed to control an escaping compressed gas 50, with the escaping compressed gas 50 extending the support legs 22. Preferably the housing 48 is comprised of housing 48 pieces and components 52, which are sealed, preferably with a gasket sealant 54, wherein the supplied compressed air exits the housing 48 proximate the extendable support legs 22 with the supplied compressed gas 50 extending the legs 22.

The invention includes a method of making an electronic circuit board 24 fixturing support device 20 for supporting a rigid electronic circuit board 24 member. The method includes providing a support base housing 48 including a magnetic field generator 26 for generating a magnetic field. The method includes providing a plurality of extendable support pin legs 22, the support legs 22 extendable upwardly away from the support base housing 48 into contact with a rigid electronic circuit board 24 member. The method includes disposing the extendable support legs 22 proximate the magnetic field generator 26 wherein the magnetic field magnetically locks a plurality of extended support positions of the upwardly extendable support legs 22. The method preferably includes providing a compressed gas conduit 56 with the compressed has conduit 56 sealed with the support base housing 48 wherein a compressed has 50 supplied by the compressed has conduit 56 extends the extendable support pin legs 22 away from the housing 48. Preferably the method includes providing a first magnetic field generator 26 electromagnetic coil 30 and a first set of extendable support legs 22 and a second magnetic field generator 26 electromagnetic coil 30 and a second set of extendable support legs 22 wherein the first electromagnetic coil 30 is energized to magnetically lock the extended support positions of the first set of extendable support legs 22, and the second electromagnetic coil 30 is energized to magnetically lock the extended support positions of the second set of extendable support legs 22. Preferably multiple rows of support legs 22 are locked by corresponding multiple longitudinally extending electromagnetic coils 30. Preferably the method includes pneumatically sealing the housing 48 to control an escaping compressed gas 50, preferably with the escaping compressed gas 50 extending the support legs 22. Preferably the housing 48 is sealed with a gasket sealant 54 such that supplied compressed air exits housing 48 proximate the extendable support legs 22 with the supplied compressed gas 50 extending the legs 22.

The invention includes a method of supporting a rigid electronic circuit board 24 member. The method includes providing a rigid member 24 to be supported and providing a rigid member support device 20 including a magnetic field generator 26 for generating a magnetic field, with the rigid member support device 20 including a plurality of extendable support pin legs 22. The method includes extending the extendable support pin legs 22 into contact with the rigid member 24 and generating a magnetic field with the magnetic field generator 26 to lock the extended support legs 22 in contact with the rigid member 24 wherein the extended support legs 22 temporarily support the rigid member 24 during an electronic circuit board 24 assembly process 28. Extending the extendable support pin legs 22 into contact with the rigid member 24 preferably includes pneumatically extending the support legs 22 into contact with the rigid member. Preferably the provided magnetic field generator 26 is comprised of a electromagnetic coil 30 and generating the locking magnetic field preferably includes supplied a locking electrical current to the coil to generate the magnetic field to lock the extend support positions of the support legs 22. Preferably the provided magnetic field generator 26 includes magnetic poles 32 (N and S), which magnetically frictionally engage the support legs 22 to lock the extended support position of the support legs 22. Preferably the method includes reversing the supplied locking electrical current to provide a demagnetizing field wherein the extended support positions of the support legs 22 are unlocked. Preferably the plurality of extendable support pin legs 22 include a first leg 34, a second leg 36, and a third leg 38 and the first leg 34 is raised to a first length supporting position 40, the second leg 36 is raised to a second length supporting position 42, and the third leg 38 is raised to a third length supporting position 44, preferably with the supporting position lengths non-equal. Preferably supporting position leg heights are independent of each other, with the legs 22 extended until they come into supporting contact with the rigid circuit board and its rigid underside components 52. Providing a support device 20 including a magnetic field generator 26 for generating a magnetic field and a plurality of extendable support legs 22, preferably includes providing the support device 20 with a first magnetic field generator 26 electromagnetic coil 30 and a first set of corresponding extendable support legs 22, a second magnetic field generator 26 electromagnetic coil 30 and a second set of corresponding extendable support legs 22 wherein the first electromagnetic coil 30 is energized to magnetically lock the extended support positions of the first set of extended support legs 22, and the second electromagnetic coil 30 is energized to magnetically lock the extended support positions of the second set of extendable support legs 22. Preferably multiple longitudinally extending rows of support legs 22 are locked by corresponding multiple longitudinally extending electromagnetic coils 30. Providing a support device 20 including a magnetic field generator 26 and a plurality of extendable support legs 22, preferably includes providing the support device 20 with a sealed housing 48, with the housing 48 pneumatically sealed to control an escaping compressed gas 50, with the escaping compressed gas 50 extending the support legs 22. Preferably the housing 48 pieces and components 52 are sealed with a gasket sealant 54 wherein compressed air exits the sealed housing 48 proximate the extendable support legs 22 with the supplied compressed gas 50 extending the legs 22.

The invention includes a rigid electronic circuit 24 member assembly fixturing support device 20 for supporting a rigid electronic circuit board 24 member during an assembly process 28. The rigid member support device 20 includes a support base and a plurality of pneumatically extendable support legs 22. The support legs 22 are pneumatically extendable upward away from the support base with the plurality of support legs 22 having a plurality of supporting leg extended lengths extended positions. The support legs 22 preferably have a distal end for engaging and supporting the board rigid member 24 when extended to the supporting leg extended lengths. The rigid member support device 20 includes an electromagnetic coil 30 for generating a magnetic field wherein the electromagnetic coil 30 magnetic field magnetically locks the supporting legs 22 extended lengths inorder to maintain the engagement and support of the electronic circuit board 24 rigid member. Preferably the fixturing support device 20 includes a compressed gas 50 source for extending the support legs 22 to the supporting leg extended lengths. Preferably the fixturing support device 20 includes a sealed housing 48 and a compressed air conduit for supplying compressed air for extending the support legs 22 to the supporting leg extended lengths, with the housing 48 pneumatically sealed to control the supplied escaping compressed gas 50, with the escaping compressed gas 50 extending the support legs 22. Preferably the housing 48 is sealed with a gasket sealant 54 wherein compressed air exits the sealed housing 48 proximate the extendable support legs 22 with the supplied compressed gas 50 extending the legs 22.

The invention includes a method of locking a position of a member. The method includes providing a magnetic position lock. The magnetic position lock includes an electromagnetic coil 30 magnetic field generator 26 with a first pole member and a second pole member. The magnetic position lock includes a magnetic position lock target, with the magnetic position lock target proximate the electromagnetic coil 30 magnetic field generator 26, with the magnetic position lock target movable relative to the electromagnetic coil 30 magnetic field generator 26. The method includes supplying a locking direct current to the electromagnetic coil 30 magnetic field generator 26 to lock a movable position of the magnetic position lock target into a magnetically locked position. The method includes supplying an unlocking reverse direction direct current to the electromagnetic coil 30 magnetic field generator 26 to unlock the magnetic position lock target from the magnetically locked position. Preferably the reverse current forms a repelling magnetic field to disengage the target so the magnetic position lock target is again movable relative to the electromagnetic coil 30 magnetic field generator 26. Preferably the reverse current is a current pulse which is relatively short and of less amperage than the longer duration locking current, such as 1 amp 150 ohm continuous locking current for about two to twenty seconds followed by a ⅓ amp current pulse for about 0.1 second for unlocking demagnetizing of the locked target position.

The magnetic position locking auto-adjusting, independent-pin circuit board support system provides vastly improved replacement for the existing board support blocks used with electronic circuit board 24 component mounting systems and high-speed electronic component mounting systems. Existing circuit board support system utilizes an array of fixed length pins. These pins are arranged during an external set-up procedure to match a specific component arrangement and board cutouts. Once an appropriate pin arrangement has been determined and the pins placed, the board support block is mounted in the machine.

In operation, the board support block is initially positioned at a low position that allows sufficient open space between the tips of the pins and the components 52 on the underside of the board for uninhibited board transport. Once the board is locked in position, the support block is raised until the pins contact the board surface. As all pins have the same length it is necessary that the pins be carefully positioned to avoid hitting any components 52 and to provide sufficient board support taking into account slots and cutouts. Errors in board position can result is improper support and damage to underside components 52.

The magnetic position locking auto-adjusting, independent-pin, circuit board support device 20 avoids such problems while also increasing circuit board throughput by reducing or eliminating changeover time.

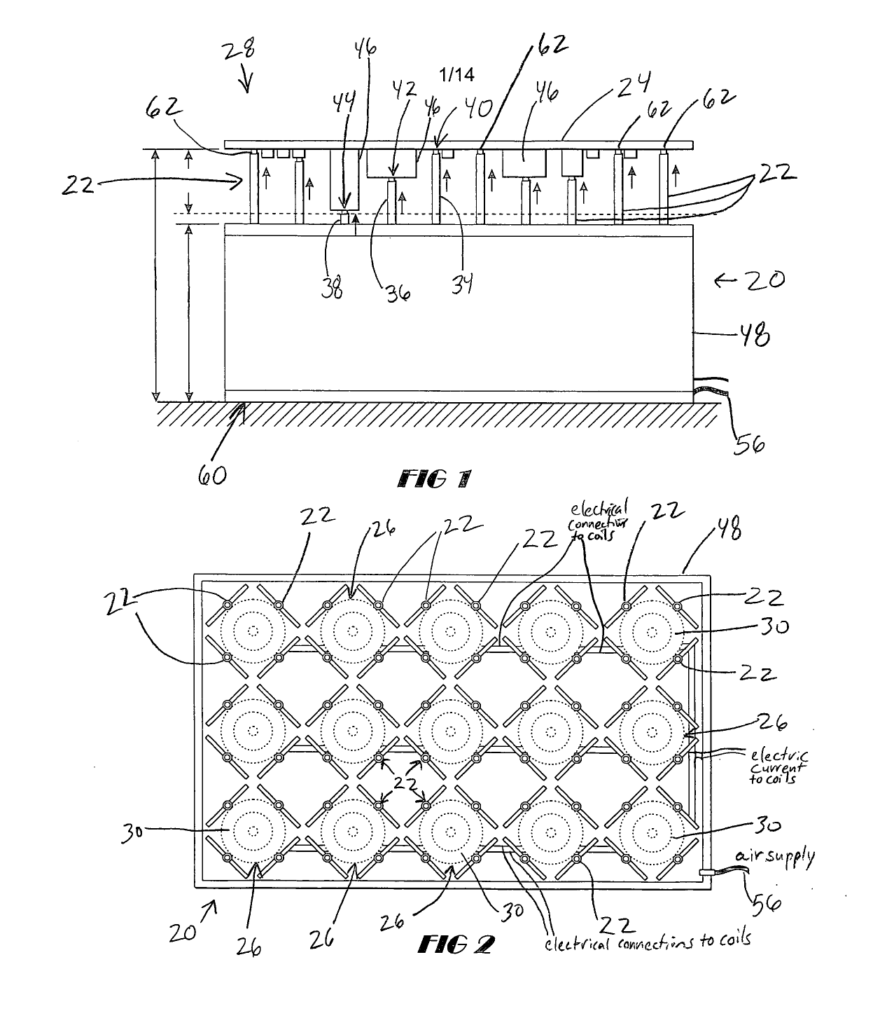

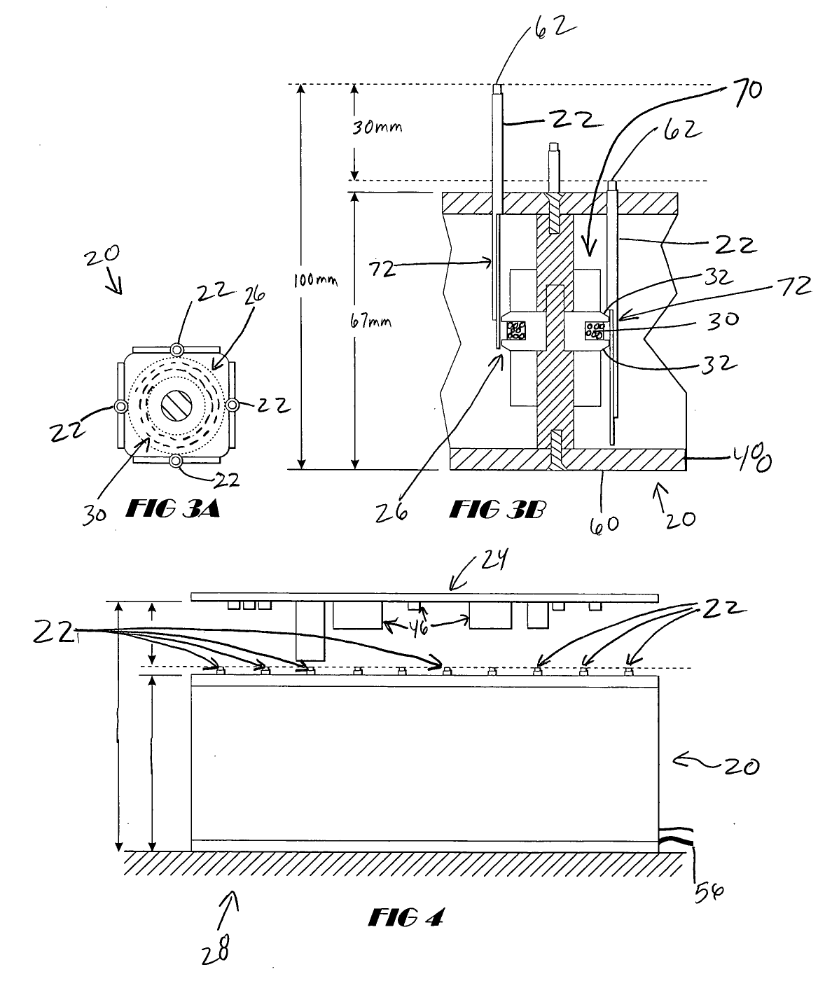

An embodiment of the magnetic position locking circuit board support device 20 and system is shown in FIG. 1-7. The device and system is based on a circuit board support block element that consists of 60 independent support pine legs 22 on 20 mm centers spaced in a 120 mm×20 mm block. Initially all of the pins are in a fully retracted down position that allows sufficient clearance (such as about 30 mm) for circuit board transport. Once the circuit board is locked in position, air is supplied to the device to lift and extend the support pins into extended support position. Each pin is able to move independently until it contacts either the underside of the circuit board or a circuit board component. At this stage the force exerted by an individual pin is preferably about 0.5-1 N depending on the air pressure. Once the pins have found their proper extended support position, the internal magnetically locking clamp magnetic position locks are energized to lock the pins in place. As shown in FIGS. 2 and 3, each magnetic position lock electromagnetic coil 30 is surrounded by four pins that are attached to a flat planar rectangular magnetically permeable (preferably steel) plate magnetic target or flag. When the coil is energized the steel plate target is attracted to the facing poles of the electromagnet and held in position by friction. The holding force id determined by the product of the magnetic attraction force and the coefficient of friction between the steel plate target and the pole tips. The holding force on each pin is preferably about 10 N. After the electronic components 52 have been placed and attached on the upper board surface during a circuit board assembly process 28, the magnetic position locks are unlocked and released and the air pressure is not supplied inorder to allow the extended pins to fall back to their fully retracted position and permitting further assembly unimpeded transport of the circuit board. Unlike the standard fixed-pin support block that is lifted as an entire unit to contact the board, only the pins are lifted. Preferably the distal ends of the individual pins are provided with compliant support tips, such as rubber elements to provide a gentle touch.

FIG. 8 compares the operation of the standard board support block with that of the magnetically locked independent-pin board support device 20.

Nominal Specification:

| | |
|---|---|
| Number of independent pins: | 60 |
| Pin arrangement: | 6 × 10 array on 20 mm centers |
| Maximum Pin Extension: | 30 mm |
| Size of support block: | 120 × 200 mm* |
| Electric Power: | ˜250 mA @ 12 volts to lock pins in place |
| Air Supply: | 20-30 PSI (140-210 kPA) to raise pins |

*4 block elements may be combined to from a 240 × 400 block

The invention provides an adaptable fixturing device for supporting circuit board that are being populated with components 52 in a high-speed component mounting machine. The invention includes an array of independently extendable pins that are lifted into position by air pressure. Electromagnetic position locking elements are then activated to lock the pins in position and provide support from below to a circuit board while components 52 are mounted on the upper surface. The independent nature of the pins allows accommodation of various sized components 52 on the underside of the board and enable high throughput and greater accuracy in high speed circuit board assembly machines.

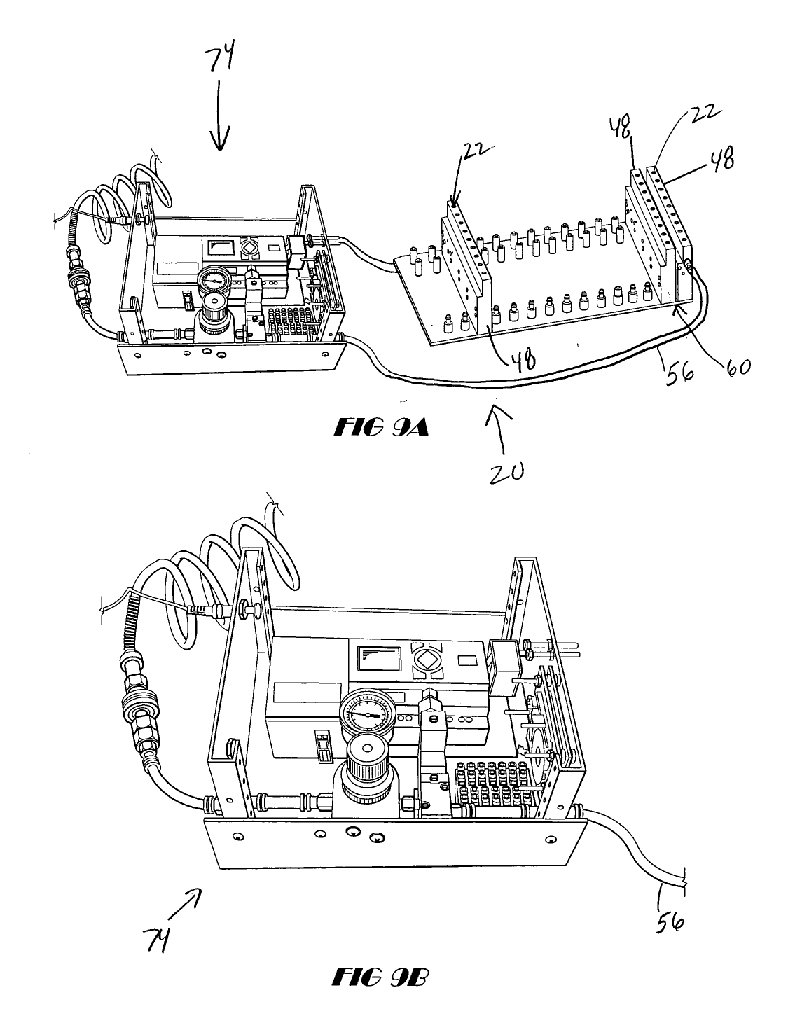

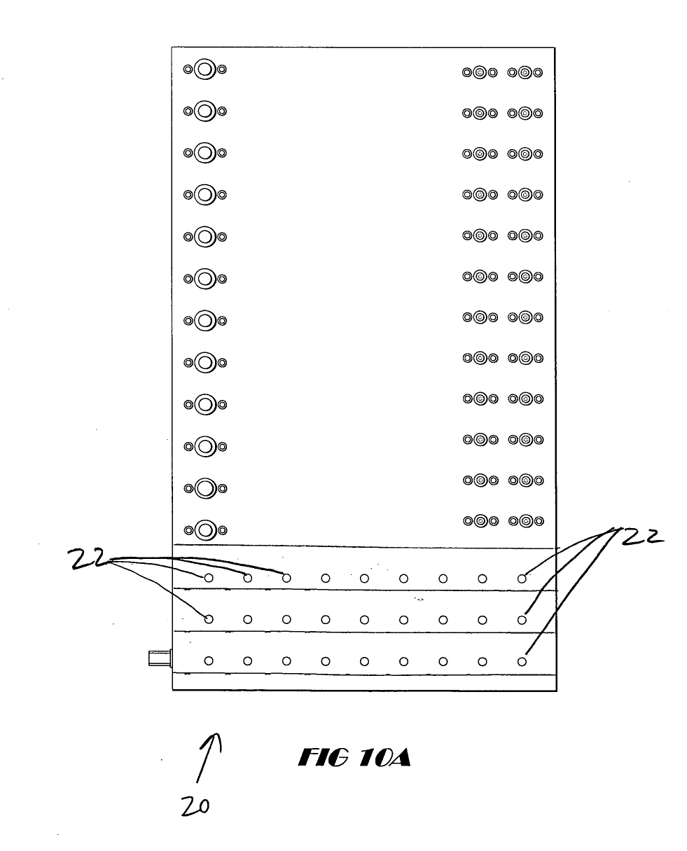

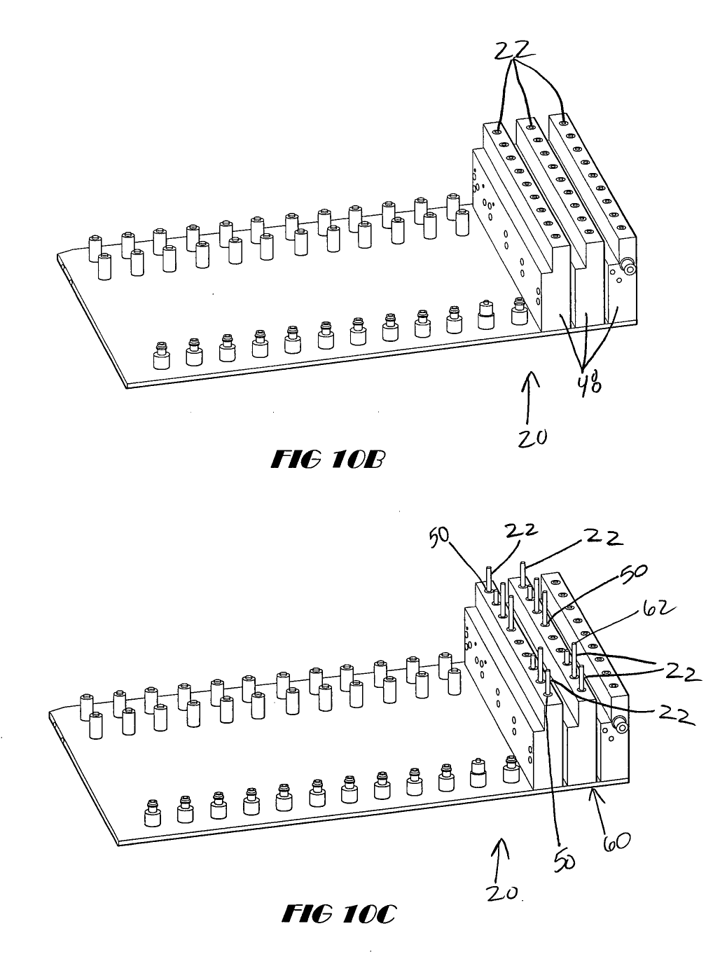

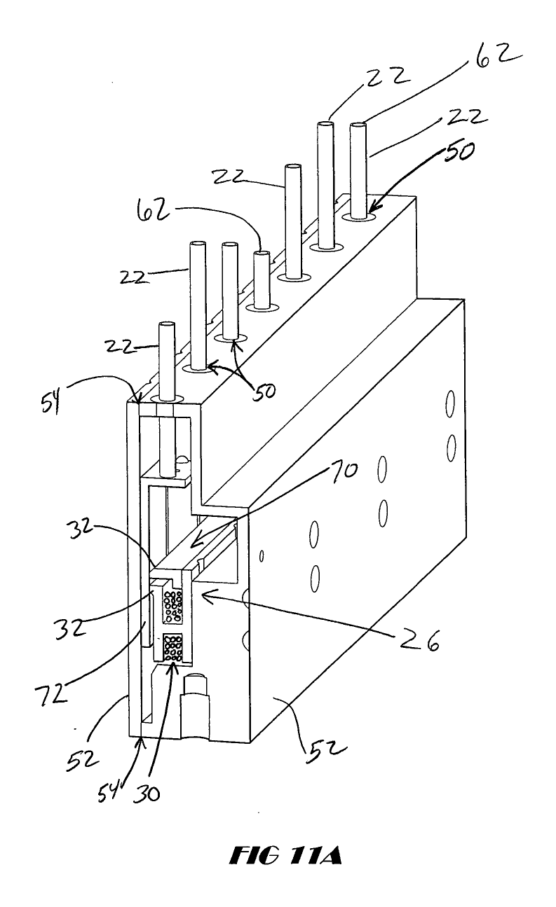

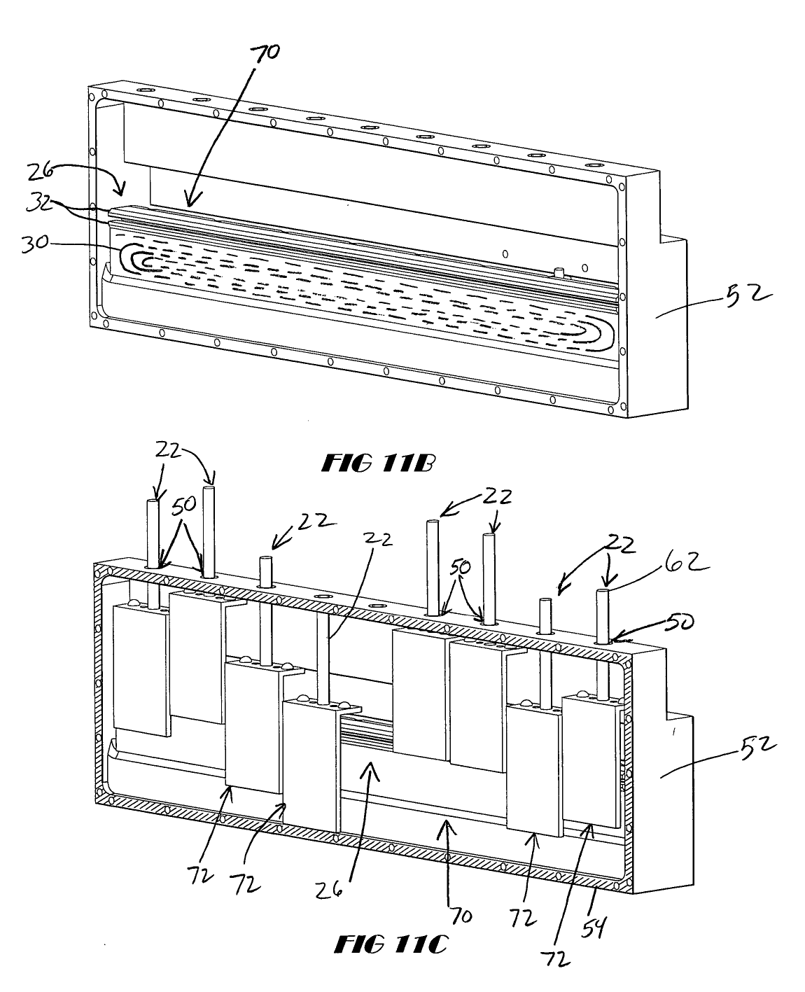

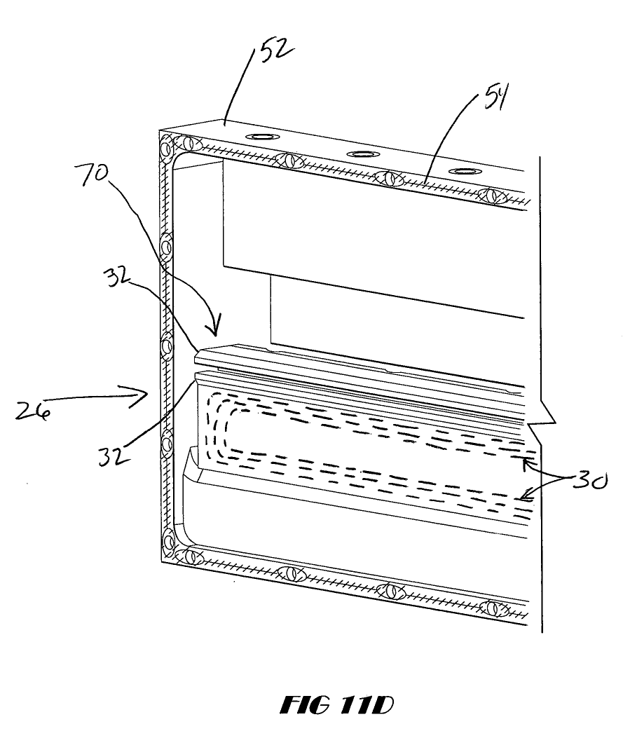

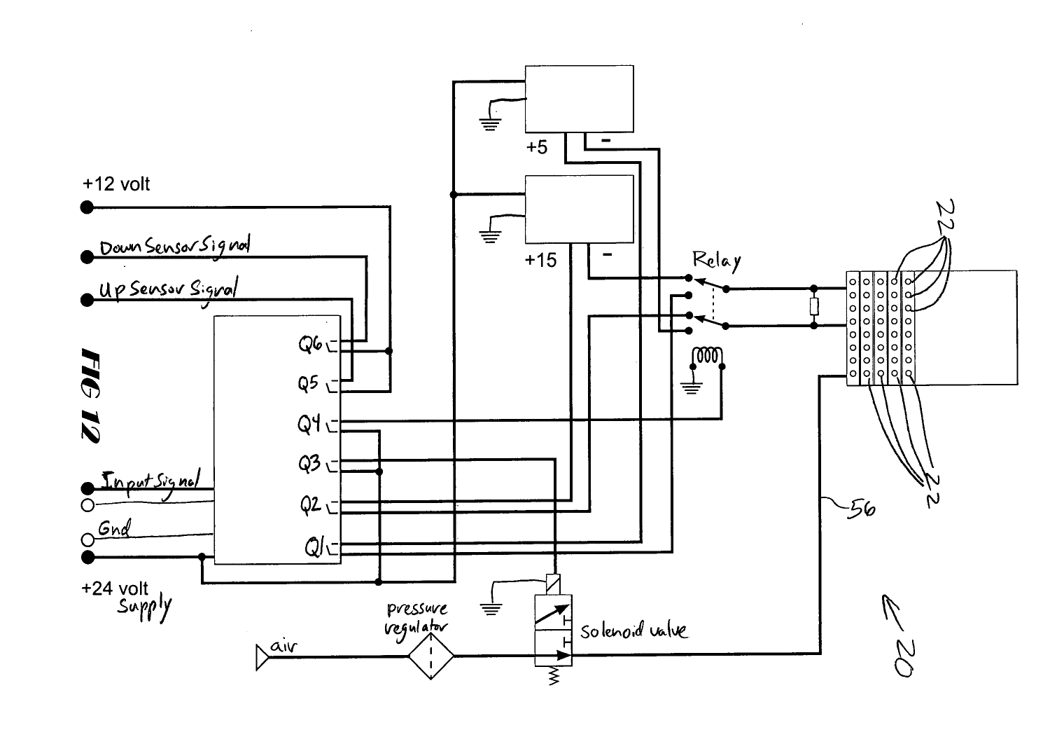

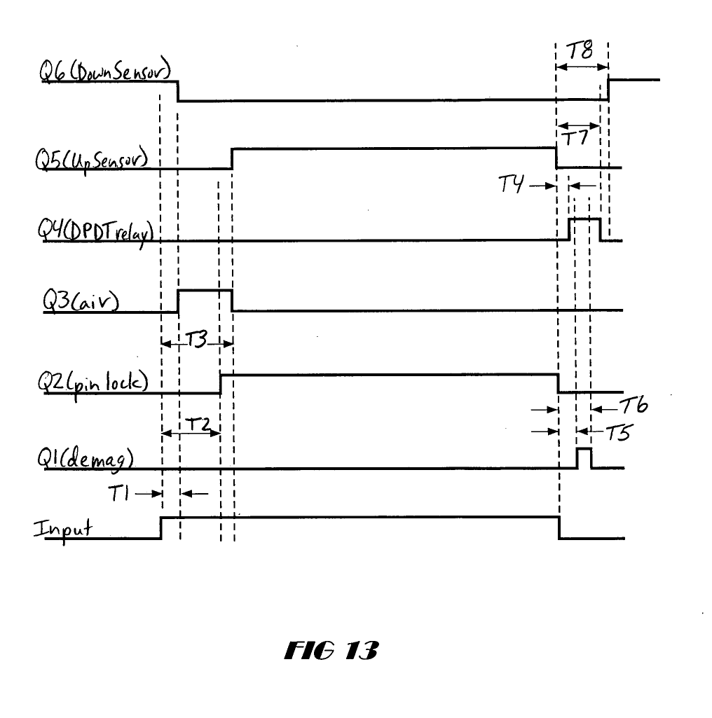

FIG. 9-13 show embodiments of the invention. FIG 9A-B show embodiments of electronic circuit board 24 assembly fixturing support device 20 and system. FIG. 9A shows the electronic circuit board 24 assembly fixturing support device 20 including a controller for providing a controlled supply of compressed air and electrical current for controlling the operation of the device, with FIG. 9B showing a closeup of the controller. As shown in FIG. 9A-B, preferably the device is comprised of modular support base longitudinal housing 48, with each housing 48 including a longitudinal row of pin legs 22. FIG. 10A shows a top plain view of the device with three modular support base longitudinal housings 48 installed on the larger devise support base. FIG. 10B shows a perspective view of the device of FIG. 10A with the support pin legs 22 of the three modular support base longitudinal housings 48 in their nonextended position. FIG. 10C shows a perspective view of the device of FIGS. 10A and 10B with a plurality of the support pin legs 22 in extended upward away locked positions. FIG. 11A-D show the interior of a modular support base longitudinal housing 48, including the magnetic field generator 26 electromagnetically locking the positions of extended pin legs 22. FIG. 12 shows a control system for supplying electrical current and compressed air in operation with a magnetic locking pin array of the device with five rows of modular housed support pin legs 22. FIG. 13 shows a control logic for operation of the device including the supply of compressed air to extend the pin legs 22, supply of a locking current to lock the pin legs 22, and supply of the demagnetizing current to unlock the locked position of the pin legs 22.

It will be apparent to those skilled in the art that various modifications and variations can be made to the present invention without departing from the spirit and scope of the invention. Thus, it is intended that the present invention cover the modifications and variations of this invention provided they come within the scope of the appended claims and their equivalents.

1. A electronic circuit board assembly fixturing support device for supporting an electronic circuit board during an assembly process, said electronic circuit board support device comprised of a support base and a plurality of extendable support legs, said support legs extendable outward from said support base with a supporting leg extended length, said support legs having a distal end for engaging and supporting said electronic circuit board when extended to said supporting leg extended lengths, and a magnetic field generator for generating a magnetic field wherein said magnetic field generator magnetic field magnetically locks the supporting legs extended lengths in order to maintain the engagement and support of the electronic circuit board.

2. A device as claimed in claim 1 wherein said device includes a compressed gas source for extending said support legs to said supporting leg extended lengths.

3. A device as claimed in claim 1 wherein said device includes a compressed air conduit for supplying compressed air for extending said support legs to said supporting leg extended lengths.

4. A device as claimed in claim 1 wherein said device includes a first magnetic pole piece, a second magnetic pole piece, and an electromagnetic coil wherein a current supplied to said coil magnetically locks a plurality of said supporting legs with said supporting legs extended lengths.

5. A device as claimed in claim 1 wherein said support base is composed of a housing, said housing pneumatically sealed to control an escaping compressed gas.

6. A method of making an electronic circuit board assembly, said method including the steps of: providing an electronic circuit board, providing an electronic circuit board support device including a magnetic field generator, said electronic circuit board support device including a plurality of extendable support legs, extending said extendable support legs into contact with said electronic circuit board, generating a magnetic field with said magnetic field generator to lock the extended support legs in contact with said electronic circuit board wherein said extended support legs support said electronic circuit board during an electronic circuit board assembly process.

7. A method as claimed in claim 6, wherein extending said extendable support legs into contact with said electronic circuit board comprises pneumatically extending said support legs into contact with said electronic circuit board.

8. A method as claimed in claim 6, wherein said magnetic field generator is comprised of a electronic coil and generating said locking magnetic field includes supplying a locking electrical current to generate said magnetic field to lock the extend support positions of said support legs.

9. A method claimed in claim 8, wherein said method includes reversing said electrical current to provide a demagnetizing field wherein said extended support positions of said support legs are unlocked.

10. A method as claimed in claim 6, wherein said plurality of extendable support legs includes a first leg, a second leg, and a third leg and said first leg is raised to a first length supporting position, said second leg is raised to a second length supporting position, and said third leg is raised to a third length supporting position.

11. A method as claimed in claim 6, wherein providing an electronic circuit board support device including a magnetic field generator and a plurality of extendable support legs, including providing said electronic circuit board support device with a first magnetic field generator electromagnetic coil and a first set of extendable support legs, a second magnetic field generator electromagnetic coil and a second set of extendable support legs wherein said first electromagnetic coil is energized to magnetically lock the extended support positions of said first set of extendable support legs, and said second electromagnetic coil is energized to magnetically lock the extended support positions of said second set of extendable support legs.

12. A method as claimed in claim 6, wherein said electronic circuit board support device is comprised of a housing, said housing pneumatically sealed to control an escaping compressed gas, with said escaping compressed gas extending said support legs.

13. A method of making an electronic circuit board fixturing support device for supporting an electronic circuit board, said method including the steps of: providing a support base housing, said support base housing including a magnetic field generator for generating a magnetic field, providing a plurality of extendable support legs, said support legs extendable upwardly away from said support base housing into contact with an electronic circuit board, and disposing said extendable support legs proximate said magnetic field generator wherein said magnetic field magnetically locks a plurality of extended support positions of said upwardly extendable support legs.

14. A method as claimed in claim 13, said method including providing a compressed gas conduit, said compressed gas conduit sealed with said support base housing wherein a compressed has supplied by said compressed gas conduit extends said extendable support legs away from said housing.

15. A method as claimed in claim 13, said method including providing a magnetic field generator electromagnetic coil and a first set of extendable support legs and a second magnetic field generator electromagnetic coil and a second set of extendable support legs wherein said first electromagnetic coil is energized to magnetically lock the extended support positions of said first set of extendable support legs, and said second electromagnetic coil is energized to magnetically lock the extended support positions of said second set of extendable support legs.

16. A method as claimed in claim 13, said method including pneumatically sealing said housing to control an escaping compressed gas.

17. A method of supporting a rigid member, said method including the steps of:
providing a rigid member to be supported, providing a rigid member support device including a magnetic field generator, said rigid member support device including a plurality of extendable support legs, extending said extendable support legs into contact with said rigid member, generating a magnetic field with said magnetic field generator to lock the extended support legs in contact with said rigid member wherein said extended support legs temporarily support said rigid member.

18. A method as claimed in claim 17, wherein extending said extendable support legs into contact with said rigid member comprises pneumatically extending said support legs into contact with said rigid member.

19. A method as claimed in claim 17, wherein said magnetic field generator is comprised of a electromagnetic coil and generating said locking magnetic field includes supplying a locking electrical current to generate said magnetic field to lock the extend support positions of said support legs.

20. A method as claimed in claim 19, wherein said method includes reversing said electrical current to provide a demagnetizing field wherein said extended support positions of said support legs are unlocked.

21. A method as claimed in claim 17, wherein said plurality of extendable support legs includes a first leg, a second leg, and a third leg and said first leg is raised to a first length supporting position, said second leg is raised to a second length supporting position, and said third leg is raised to a third length supporting position.

22. A method as claimed in claim 17, wherein providing a support device including a magnetic field generator and a plurality of extendable support legs, includes providing said support device with a first magnetic field generator electromagnetic coil and a first set of extendable support legs, a second magnetic field generator electromagnetic coil and a second set of extendable support legs wherein said first electromagnetic coil is energized to magnetically lock the extended support positions of said first set of extendable support legs, and said second electromagnetic coil is energized to magnetically lock the extended support positions of said second set of extendable support legs.

23. A method as claimed in claim 17, wherein providing a support device including a magnetic field generator and a plurality of extendable support legs, includes providing said support device with a sealed housing, said housing pneumatically sealed to control an escaping compressed gas, with said escaping compressed gas extending said support legs.

24. A rigid member assembly fixturing support device for supporting a rigid member, said rigid member support device comprised of a support base and a plurality of pneumatically extendable support legs, said support legs pneumatically extendable upward from said support base with said plurality of support legs having a plurality of supporting leg extended lengths, said support legs having a distal end for engaging and supporting said rigid member when extended to said supporting leg extended lengths, and an electromagnetic coil for generating a magnetic field wherein said electromagnetic coil magnetic field magnetically locks the supporting legs extended lengths in order to maintain the engagement and support of the rigid member.

25. A method of locking a position of a member, said method comprised of: providing a magnetic position lock, said magnetic position lock comprised of an electromagnetic coil magnetic field generator with a first pole member and a second pole member, said magnetic position lock including a magnetic position lock target, said magnetic position lock target proximate said electromagnetic coil magnetic field generator, said magnetic position lock target movable relative to said electromagnetic coil magnetic field generator, supplying a locking current to said electromagnetic coil magnetic field generator to lock a movable position of said magnetic position lock target into a magnetically locked position, supplying an unlocking current to said electromagnetic coil magnetic field generator to unlock said magnetic position lock target from said magnetically locked position.

26. A method of making an electronic circuit board assembly, said method comprised of: providing a magnetic position lock, said magnetic position lock comprised of an electromagnetic coil magnetic field generator with a first pole member and a second pole member, said magnetic position lock including a magnetic position lock target, said magnetic position lock target proximate said electromagnetic coil magnetic field generator, said magnetic position lock target movable relative to said electromagnetic coil magnetic field generator, supplying a locking current to said electromagnetic coil magnetic field generator to lock a movable position of said magnetic position lock target into a magnetically locked position during an electronic circuit board assembly process, supplying an unlocking current to said electromagnetic coil magnetic field generator to unlock said magnetic position lock target from said magnetically locked position after said electronic circuit board assembly process.
